(19) United States
(12) Patent Application Publication
(10) Pub. No.: US 2005/0253259 A1
(43) Pub. Date: Nov. 17, 2005

(54) Integrated circuit packaging method and structure for redistributing configuration thereof

(75) Inventors: Chih Hsiang Lin, Hsin_Chu (TW); Yueh-Chiu Chung, Hsin_Chu (TW); Cheng-Hung Shih, Hsinchu City (TW)

Correspondence Address: SNELL & WILMER;ONE ARIZONA CENTER, 400 EAST VAN BUREN, PHOENIX, AZ, 850040001, US

(73) Assignee: CHIPLUS SEMICONDUCTOR CORPORATION

(21) Appl. No.: 11/113,488

(22) Filed: Apr. 25, 2005

(30) Foreign Application Priority Data
Apr. 23, 2004 (TW) 93111536

(51) Int. Cl. H01L 23/495

(52) U.S. Cl. 257/734

(57) ABSTRACT

A packaging method and structure for altering the configuration of an integrated circuit are disclosed. The packaging structure includes a die, a redistribution layer, a lead frame, and a passivation layer. The die has a plurality of first pads and the lead frame has a plurality of lead pads. The coupling between the first pads and the lead pads together define a first configuration. The redistribution layer includes a plurality of second pads and a plurality of wires. The wires selectively connect at least a portion of the first pads and the second pads; thus the couplings between the second pads and the lead pads together define a second configuration. Then the second pads electrically couple respectively to the lead pads in accordance with the second configuration.

### CROSS-REFERENCE TO RELATED APPLICATIONS

This application claims priority of Taiwan Patent Application Serial No. 093111536 entitled “Integrated Circuit Packaging Method and Structure for Redistributing Configuration Thereof,” filed on Apr. 23, 2004.

### FIELD OF INVENTION

The present invention relates to a method and structure for packaging an integrated circuit, particularly to a packaging method and structure for altering (redistributing) the input/output configuration of an integrated circuit.

### BACKGROUND OF THE INVENTION

As the semiconductor technology develops, the integrated circuit is broadly used in various kinds of electronics equipment, such as personal computer, notebook, personal digital assistant, mobile phone, and the like. The design/manufacture of an integrated circuit, however, usually faces a problem of configuration complexity. For example, in the field of dynamic random access memory (DRAM) and flash memory, many configurations are present in response to various applications; even the equipment has the same storage space. The specification standards of memory module are developed by some semiconductor industrial standardize organizations, such as JEDEC solid technology association.

Traditionally, one kind of die is packaged with a specific lead frame to fabricate one configuration of semiconductor memory device. And a new design of die is required for another configuration of memory device, and a corresponding new manufacturing process is then required. Redesigning a die is expensive due to additional processing, such as using a new mask during the photolithography process. Further, the originally prepared die is unable to be used for a new configuration. The above-mentioned problems relate to not only the manufacturing cost, but also the difficulty of inventory management.

Therefore, it is advantageous to provide a packaging method and structure to reduce the manufacturing cost and efficiently fabricate integrated circuit devices with different kind of configurations.

### SUMMARY OF THE INVENTION

It is one aspect of the present invention to provide an integrated circuit packaging method for altering (redistributing) the input/output configuration, and fabricating various integrated circuit modules with different configurations.

It is another aspect of the present invention to provide an integrated circuit packing structure using the same die to fabricate integrated circuit modules with different configurations, with benefits of not only lowering the manufacture cost but also improving the efficiency.

An integrated circuit packaging method in accordance with one embodiment of the present invention is disclosed. A die is electrically coupled to a lead frame. The die has a plurality of first pads, and the lead frame has a plurality of lead pads. The plurality of first pads and the plurality of lead pads together define a first configuration. An integrated circuit device is packed by electrically coupling the plurality of first pad to the plurality of lead pad according to the first configuration.

In this embodiment of the present invention, an integrated circuit device with a second configuration is packed by altering the input/output configuration of the die. The method includes the following steps. A plurality of second pads are formed on the die. A plurality of wires are formed for selectively connecting at least a portion of the plurality of first pads to the plurality of second pads, and the plurality of second pads are electrically coupled to the plurality of the lead pads. The plurality of second pads and the plurality of lead pads together define a second configuration. Thus, an integrated circuit device with a second configuration is packed by electrically coupling the plurality of second pads to the plurality of the lead pads according to the second configuration. A passivation layer is formed on the die to protect the die.

An integrated circuit packaging structure in accordance with another embodiment of the present invention is disclosed. The integrated circuit packaging structure electrically couples a die to a lead frame. The die has a plurality of first pads, and the lead frame has a plurality of lead pads. The plurality of first pads and the plurality of lead pads together define a first configuration. An integrated circuit device is packed by electrically coupling the plurality of first pads to the plurality of lead pads according to the first configuration.

The integrated circuit packaging structure in accordance with the present invention includes a redistribution layer and a passivation layer. The redistribution layer has a plurality of second pads and a plurality of wires. The plurality of wires selectively connects at least a portion of the plurality of first pads to the plurality of second pads, and the plurality of second pads and the plurality of lead pads together define a second configuration. An integrated circuit device is packed by electrically coupling the plurality of second pad to the plurality of lead pad according to the second configuration. The passivation layer is formed on the die to protect the die.

### BRIEF DESCRIPTION OF THE DRAWINGS

FIG. 1 shows an integrated circuit in accordance with one embodiment of the present invention;

FIG. 2 shows an integrated circuit in accordance with another embodiment of the present invention;

FIG. 3 shows an integrated circuit packaging structure in accordance with an embodiment of the present invention; and

FIG. 4 shows a cross-sectional view of an integrated circuit packaging structure in accordance with the present invention.

### DETAILED DESCRIPTION

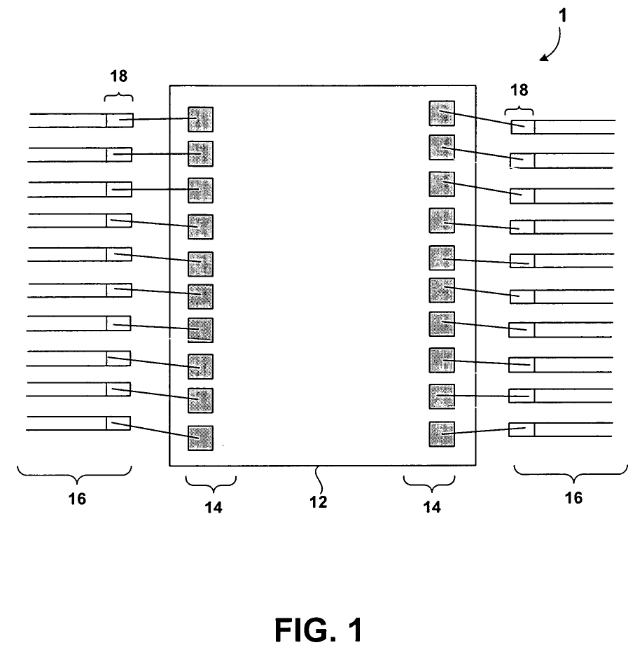

FIG. 1 shows an integrated circuit 1 using the packaging method in accordance with an embodiment of the present invention. Referring the FIG. 1, die 12 is electrically coupled to a lead frame 16. In this embodiment, die 12 implements a Complementary Metal Oxide Semiconductor (CMOS) Static Random Access Memory (SRAM). Die 12 has a plurality of first pads 14. The lead frame 16 has a plurality of lead pads 18. The plurality of first pads 14 and the plurality of lead pads 18 together define a first configuration. An integrated circuit 1 of the first configuration is obtained by electrically coupling the plurality of first pad 14 to the plurality of lead pad 18. For example, the integrated circuit 1 in this embodiment is a memory module with 256 k*16 bits.

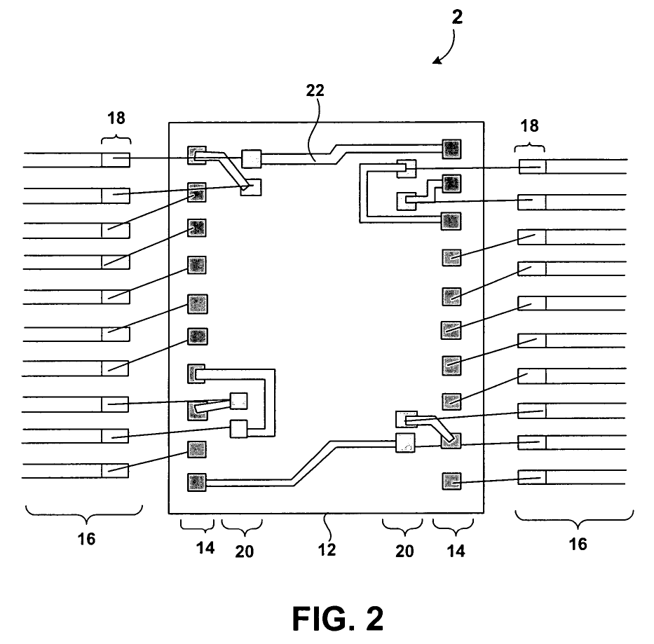

Referring to FIG. 2, an integrated circuit 2 with a second configuration is packed by altering (redistributing) the input/output configuration of the die 12. For example, the integrated circuit 2 in this embodiment is a memory module with 512 k*8 bits. The method includes the following steps. A plurality of second pads 20 are formed on the surface of die 12. A plurality of wires 22 are formed for selectively connecting at least a portion of the plurality of first pads 14 to the plurality of second pads 20. The term “selectively connecting” here means to connect either according the first configuration, the second configuration, or other input/output configurations (i.e. 256 k*16 bits and 512 k*8 bits in this embodiment). The material of plurality of wires includes aluminum, gold, cupper, nickel, titanium, or the likes. The plurality of second pads 20 are electrically coupled to the plurality of the lead pads 18. The plurality of second pads 20 and the plurality of lead pads 18 together define a second configuration. Thus, an integrated circuit 2 with a second configuration is packed by electrically coupling the plurality of second pads 20 to the plurality of the lead pads 18 according to the second configuration. A passivation layer (not shown) is formed on the die to protect the die 12.

The present invention fabricates integrated circuits with different configurations without changing the internal design of die 12. Integrated circuit 1, integrated circuit 2, and IC with other configurations are packed by altering the input/output of die 12. Therefore, the manufacture cost, such as costs associated with the mask used during a photolithography process, is significantly reduced. Further, one kind of die, usable for fabricating devices with different configurations, simplifies the management of production, thus reducing the risk of high inventory.

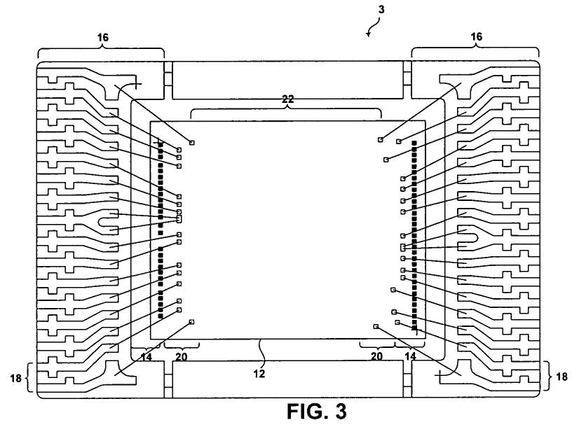

FIG. 3 shows an integrated circuit 3 in accordance with another embodiment of the present invention. In integrated circuit 3, a die 12 is electrically coupled to a lead frame 16. In this embodiment, die 12 includes, but not limited to, a CMOS SRAM. The embodiment of the present invention includes various kinds of packaging structures, such as TSOP, SOP, STSOP, CSP, BGA, etc. Die 12 has a plurality of first pads 14. The lead frame 16 has a plurality of lead pads 18. Similar to the descriptions above, the integrated circuit 3 is packed either according to a first configuration, a second configuration, or other configurations. The integrated circuit 3 is packed by electrically coupling the plurality of first pad 14 to the plurality of lead pad 18 according to the first configuration. For example, the integrated circuit 3 in this embodiment is a memory module with 256 k*16 bits. Alternatively, the integrated circuit 3 is packed by electrically coupling the plurality of second pads 20 to the plurality of the lead pads 18 according to the second configuration.

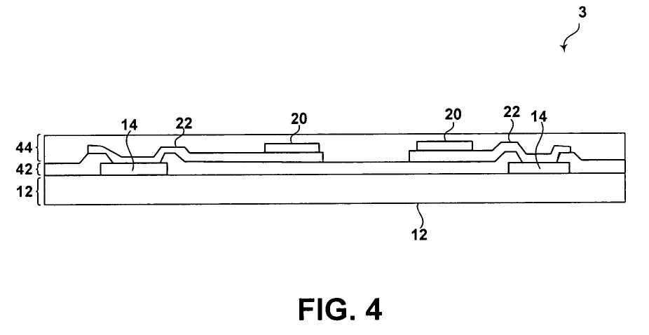

FIG. 4 shows a cross-sectional view of an integrated circuit 3 in accordance with the present invention. The integrated circuit 3 includes a redistribution layer 42 and a passivation layer 44. The redistribution layer 42 has a plurality of second pads 20 and a plurality of wires 22. The plurality of wires 22 selectively connects at least a portion of the plurality of first pads 14 to the plurality of second pads 20, and the plurality of second pads 20 and the plurality of lead pads 18 together define a second configuration. The material suitable to form the plurality of wires 22 includes aluminum, gold, cupper, nickel, titanium, or the like. An integrated circuit 3 is packed by electrically coupling the plurality of second pad 20 to the plurality of lead pad 18 according to the second configuration. The passivation layer 44 is formed on the die to protect the die.

The packaging structure of integrated circuit 3 alters input/output of the die 12 using the redistribution layer without changing the internal design of die 12, and devices with different kinds of configurations are able to be made. Therefore, the manufacture cost is significantly reduced, such as costs associated with the mask used during photolithography processing. Further, one kind of die, usable for fabricating devices with different configurations, simplifies the management of production, and thus the risk of high inventory is also reduced.

1. An integrated circuit packaging method for electrically coupling a die to a lead frame, the die having a plurality of first pads and the lead frame having a plurality of lead pads, and the plurality of first pads and the plurality of lead pads together defining a first configuration, the method comprising the steps of:
forming a plurality of second pads on the die;
forming a plurality of wires for selectively connecting at least a portion of the plurality of first pads to the plurality of second pads; and
electrically coupling the plurality of second pads to the plurality of the lead pads, wherein the plurality of second pads and the plurality of lead pads together define a second configuration.

2. The method of claim 1, wherein the die comprises a Complementary Metal-Oxide Semiconductor (CMOS) SRAM.

3. The method of claim 2, wherein the CMOS SRAM exhibits a first specification of a word-number and a bit-number under the first configuration, and the CMOS SRAM exhibits a second specification of a word-number and a bit-number under the second configuration, and the first specification and the second specification are not identical.

4. The method of claim 1, further comprising the step of forming a passivation layer covering the die.

5. An integrated circuit packaging structure for electrically coupling a die to a lead frame, the die having a plurality of first pads and the lead frame having a plurality of lead pads, and the plurality of first pads and the plurality of lead pads together defining a first configuration, the structure comprising:
a redistribution layer on the die, the redistribution layer having:
a plurality of second pads electrically coupling to the plurality of the lead pads; and
a plurality of wires selectively connecting at least a portion of the plurality of first pads to the plurality of second pads;
wherein the plurality of second pads and the plurality of lead pads together define a second configuration.

6. The structure of claim 5, wherein the die comprises a Complementary Metal-Oxide Semiconductor (CMOS) SRAM.

7. The structure of claim 6, wherein the CMOS SRAM exhibits a first specification of a word-number and a bit-number under the first configuration, and the CMOS SRAM exhibits a second specification of a word-number and a bit-number under the second configuration, and the first specification and the second specification are not identical.

8. The method of claim 1, further comprising the step of forming a passivation layer covering the die.
